(19) United States
(12) Patent Application Publication
(10) Pub. No.: US 2009/0191472 A1
(43) Pub. Date: Jul. 30, 2009

(54) Blank Mask and Method for Fabricating the Same

(75) Inventor: Jun Chun, Incheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/347,254

(22) Filed: Dec. 31, 2008

(30) Foreign Application Priority Data
Jan. 29, 2008 (KR) 10-2008-0009235

(51) Int. Cl. G03F 1/00

(52) U.S. Cl. 430/5

(57) ABSTRACT

A blank mask includes a pattern target layer formed over a transparent substrate and a self-assembly monolayer disposed over and modifying the surface of a back side of the transparent substrate opposite to the pattern target layer.

### CROSS-REFERENCE TO RELATED APPLICATION

Priority to Korean patent application number 10-2008-0009235 filed Jan. 29, 2008, the entire disclosure of which is incorporated by reference, is claimed.

### BACKGROUND OF THE INVENTION

The invention relates generally to a semiconductor device and a method for fabricating the same and, more particularly, to a blank mask used in photolithography and a method for fabricating the same.

In a process of fabricating a semiconductor device, a photomask formed with a pattern is used to realize a desired pattern on a wafer. Since the pattern realized on the photomask is transferred onto the wafer through a photolithography process, a process of fabricating the photomask is very important.

In order to fabricate the photomask, a light shielding layer and a resist layer are formed on a substrate and exposure and development by electron beam lithography is performed on the resist layer to form a resist layer pattern. After that, the exposed portion of the light shielding layer is etched using the resist layer pattern as an etching mask to form a light shielding layer pattern.

During the photomask fabrication process, e.g. during the process using water-soluble material, such as during the development process and the cleaning process, a water-soluble stain is generated on a surface of a substrate by influence of a solvent. Specifically, a photomask substrate is formed of a transparent quartz substrate, and the quartz substrate is a SiOₓ-based material and has hydrophilic properties. When the surface of the hydrophilic quartz substrate is in contact with a water-based solvent, the solvent is spread on the surface of the substrate to result in a stain and generate foreign substances. Particularly, since the photomask fabrication process is performed with a back side of the photomask being exposed to the quartz substrate, a large amount of the water-soluble stain is generated on the back side of the photomask. The water-soluble stain acts as a factor causing defects on the wafer and has a large influence on a production yield. Also, when the water-soluble stain is generated in the photomask fabrication process, an additional cleaning process is required to remove the water-soluble stain, which increases process time and cost.

### SUMMARY OF THE INVENTION

In one embodiment, a blank mask comprises a pattern target layer formed over a transparent substrate and a self-assembly monolayer disposed over and surface modifying a back side of the transparent substrate, which is opposite to the pattern target layer.

Preferably, the pattern target layer comprises at least one of a light shielding layer and a phase shift layer.

Preferably, the blank mask further comprises a resist layer disposed over the pattern target layer.

Preferably, the self-assembly monolayer is formed using at least one monomolecular film-forming material.

Preferably, the self-assembly monolayer is formed using Octadecyl Trichloro Silane (OTS) material.

In another embodiment, a method for fabricating a blank mask comprises forming a pattern target layer over a transparent substrate, and forming a self-assembly monolayer which surface modifies a back side of the transparent substrate over the back side of the transparent substrate formed with the pattern target layer.

Preferably, the self-assembly monolayer is formed using at least one monomolecular film-forming material.

Preferably, the self-assembly monolayer is formed using Octadecyl Trichloro Silane (OTS).

Preferably, the self-assembly monolayer is formed by injecting a solution containing at least one monomolecular film-forming material while spinning the transparent substrate.

### BRIEF DESCRIPTION OF THE DRAWINGS

FIG. 1 illustrates a blank mask according to an embodiment of the invention.

FIGS. 2 and 3 illustrate a process of fabricating a blank mask according to an embodiment of the invention.

FIG. 4 illustrates a process of fabricating a blank mask according to another embodiment of the invention.

### DESCRIPTION OF SPECIFIC EMBODIMENTS

Hereinafter, preferred embodiments of the invention will be described in detail with reference to the accompanying drawings.

Referring to FIG. 1, a blank mask according to the invention includes a pattern target layer 110 disposed over a transparent substrate 100 such as quartz and a self-assembly monolayer 130 disposed over a back side of the transparent substrate 100 opposite to the pattern target layer 110 and modifying a surface of the back side of the transparent substrate 100 to render the surface hydrophobic, for example. The blank mask further includes a resist layer 120 disposed over the pattern target layer 110.

The pattern target layer 110 is, if necessary, formed of a light shielding layer, or a phase shift layer and a light shielding layer, but is not limited to such a structure. The light shielding layer is preferably formed of a material capable of shielding the transmitted light, e.g. a chrome (Cr) layer. The phase shift layer is preferably formed of a material capable of shifting the transmitted light, e.g. a molybdenum silicon oxynitride (MoSiON) layer.

The self-assembly monolayer 130 is preferably formed using at least one monomolecular film-forming material or using octadecyl trichlorosilane (OTS) material, for example. The self-assembly monolayer is illustratively a material made of CH₃(CH₂)₁₇SiCl₃ and acts to surface modify the back side of the transparent substrate 100 such as quartz to render the surface hydrophobic. Accordingly, the back side of the transparent substrate 100 is surface-modified to be hydrophobic and can thus prevent formation of a water-soluble stain otherwise generated during the photomask fabrication process using the blank mask, e.g. during the process using water-soluble material, such as during the development process and/or the cleaning process. Therefore, time and cost savings result, and the generation of the foreign substances can be inhibited by reducing additional cleaning.

Hereinafter, a method for fabricating the blank mask according to the invention is described.

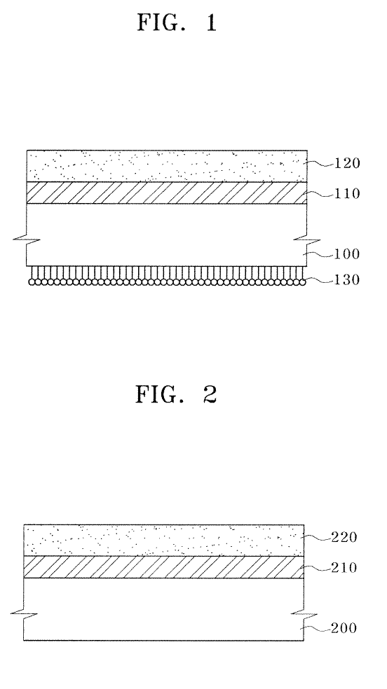

Referring to FIG. 2, a pattern target layer 210 and a resist layer 220 are formed over a transparent substrate 200, such as quartz.

The pattern target layer 210 is, if necessary, formed of a light shielding layer, or a phase shift layer and a light shielding layer, but is not limited to such a structure. The light shielding layer is preferably formed of a material capable of shielding the transmitted light, e.g. a chrome (Cr) layer. The phase shift layer is preferably formed of a material capable of shifting the transmitted light, e.g. a molybdenum silicon oxynitride (MoSiON) layer.

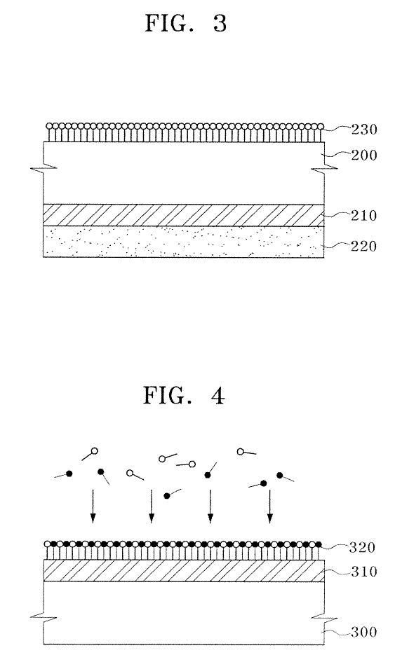

Referring to FIG. 3, a self-assembly monolayer 230 that modifies a surface, preferably to render the surface hydrophobic, is formed using a solution over a back side of the transparent substrate 200 opposite the pattern target layer 210 and the resist layer 220. The self-assembly monolayer 230 is preferably formed by loading a photomask over a spin chuck of a spinner with its back side being exposed and then injecting a solution containing at least one monomolecular film-forming material to the back side of the transparent substrate using a nozzle while spinning the spin chuck. The self-assembly monolayer 230 is preferably formed using at least one monomolecular film-forming material. Thus, a thickness of the self-assembly monolayer 230 is determined by the molecular chain length of the monomolecular film-forming material. Therefore, it is possible for the thickness of the self-assembly monolayer to be several Å to tens Å by changing the kind of the molecule used as the monomolecular film-forming material after determining the thickness of the self-assembly monolayer to be formed. For example, when forming the self-assembly monolayer 230 using the OTS material, the thickness of the self-assembly monolayer can be increased to about 3 nm.

As is apparent from the foregoing description, the back side of the transparent substrate is surface-modified to be hydrophobic by forming the self-assembly monolayer over the back side of the transparent substrate using at least one monomolecular film-forming material. Therefore, it is possible to minimize the area in contact with the back side of the transparent substrate when contacting with the aqueous solvent during the photomask fabrication process and prevent a water-soluble stain during the process using the water-soluble material, such as the development process and the cleaning process, for example. It is also possible to prevent the self-assembly monolayer and the back side of the transparent substrate from being physically damaged during the photomask fabrication process. Consequently, it is possible to save the time and reduce the process time by omitting the additional cleaning process for removing the water-soluble stain, and it is also possible to stably inhibit the generation of the foreign substances.

### Embodiment 2

Referring to FIG. 4, a pattern target layer 310 is formed over a substrate 300. Herein, the substrate may be a transparent substrate or it may be a semiconductor substrate. The pattern target layer 310 is formed of a light shielding layer, e.g. a chrome(Cr) layer. The pattern target layer 310 may be, if necessary, formed of a Molybdenum silicon oxynitride (MoSiON) layer, a polysilicon layer, or a conductive layer, but is not limited thereto.

A self-assembly monolayer 320 is formed over the pattern target layer 310 using at least two monomolecular film-forming materials, thereby modifying the surface of the pattern target layer 310. Specifically, the at least two monomolecular film-forming materials are preferably vaporized over the pattern target layer 310, and the self-assembly monolayer 320 is formed by controlling the ratio of end groups of the monomolecular film-forming materials. The self-assembly monolayer 320 modifies the surface of the pattern target layer 310 using a monomolecular film-forming material having hydrophobic molecular end groups or a monomolecular film-forming material having hydrophilic molecular end groups. The monomolecular film-forming material having hydrophobic molecular end groups is made of CH₃(CH₂)₁₇Si(OCH₃)₃ or (CH₃)₃SiNHSi(CH₃)₃. The monomolecular film-forming material having hydrophilic molecular end groups is made of CH₃(CH₂)₁₇NH₂ or CH₃(CH₂)₁₇COOH.

For example, the degree of hydrophobicity increases as the ratio of the monomolecular film-forming material having hydrophobic molecular end groups increases, and the degree of hydrophobicity decreases as the ratio of the monomolecular film-forming material having hydrophobic molecular end groups decreases.

Therefore, it is possible to modify the surface of the pattern target layer 310 by forming the self-assembly monolayer 320 with control of the ratio of the material with hydrophobic end groups and the material with hydrophilic end groups. Thus, the ratio of the material with hydrophobic end groups and the material with hydrophilic end groups can be controlled according to the kind of the resist layer formed over the pattern target layer 310 for patterning the pattern target layer 310. Therefore, in order to change the properties of the surface of the pattern target layer, it is possible to induce the surface modification by changing the ratio of at least two monomolecular film-forming materials using the at least two monomolecular film-forming materials, and it is also possible to control the degree of hydrophobicity of the surface according to the ratio of the materials. Also, it is possible to enhance the adhesive force between the pattern target layer and the resist layer formed over the pattern target layer by modifying the surface of the pattern target layer.

While the invention has been described with respect to the specific embodiments, various changes and modifications may be made without departing from the spirit and scope of the invention as defined in the following claims.

What is claimed is:

1. A blank mask, comprising:
a pattern target layer formed over a transparent substrate; and
a self-assembly monolayer disposed over and modifying a surface of a back side of the transparent substrate opposite the pattern target layer.

2. The blank mask of claim 1, wherein the pattern target layer comprises at least one of a light shielding layer and a phase shift layer.

3. The blank mask of claim 1, further comprising a resist layer disposed over the pattern target layer.

4. The blank mask of claim 1, wherein the self-assembly monolayer comprises at least one monomolecular film-forming material.

5. The blank mask of claim 1, wherein the self-assembly monolayer comprises octadecyl trichlorosilane.

6. A method for fabricating a blank mask, comprising:
forming a pattern target layer over a transparent substrate; and
forming a self-assembly monolayer that surface modifies a back side of the transparent substrate over the back side of the transparent substrate opposite the pattern target layer.

7. The method of claim 6, wherein the self-assembly monolayer comprises at least one monomolecular film-forming material.

8. The method of claim 6, wherein the self-assembly monolayer comprises octadecyl trichlorosilane.

9. The method of claim 6, comprising forming the self-assembly monolayer by injecting a solution containing at least one monomolecular film-forming material onto the transparent substrate while spinning the transparent substrate.

10. The method of claim 6, comprising forming the self-assembly monolayer using vapor deposition.

11. A method for fabricating a blank mask, comprising:
forming a pattern target layer over a substrate; and
forming a self-assembly monolayer that modifies a surface of the pattern target layer to be hydrophobic over the pattern target layer using at least two monomolecular film-forming materials.

12. The method of claim 11, comprising forming the self-assembly monolayer by:
vaporizing the at least two monomolecular film-forming materials; and
forming the self-assembly monolayer by controlling a ratio of the monomolecular film-forming materials and depositing the two monomolecular film-forming materials on the surface of the pattern target layer.

13. The method of claim 12, wherein the two monomolecular film-forming materials comprise a first material with a hydrophobic end group or a second material with a hydrophilic end group, and comprising forming the self-assembly monolayer by controlling the ratio of the material with hydrophobic end group or the material with hydrophilic end group.
